(19) United States
(12) Patent Application Publication
(10) Pub. No.: US 2010/0015810 A1
(43) Pub. Date: Jan. 21, 2010

(54) SURFACE PROCESSING METHOD AND SURFACE PROCESSING APPARATUS

(75) Inventors: Yutaro Yanagisawa, Shizuoka (JP); Katsuyoshi Fujita, Shizuoka (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K., Hamamatsu-shi, Shizuoka (JP)

(21) Appl. No.: 12/438,773

(22) PCT Filed: Jun. 22, 2007
(86) PCT No.: PCT/JP2007/062595

§ 371 Date: Apr. 8, 2009

(30) Foreign Application Priority Data
Aug. 28, 2006 (JP) 2006-231093

(51) Int. Cl. H01L 21/306

(52) U.S. Cl. 438/746; 156/345.11; 257/E21.215

(57) ABSTRACT

A processing object 2 is sucked and fixed by a sucker 11 and rotated by a rotator 12. In that state, a processing liquid supplied from a processing liquid supply 22 is applied through a processing liquid application tube 21 onto a surface of the processing object 2. Thermal electrons emitted from a thermionic source 33 are accelerated by an acceleration electrode 34 and pass through a Be film 32 to impinge upon the processing liquid on the surface of the processing object 2. When the processing liquid on the surface of the processing object is irradiated with the electron beam, the processing liquid is ionized or radicalized to become active, thereby effectively processing the surface of the processing object 2.

### TECHNICAL FIELD

The present invention relates to a method and apparatus for processing a surface of a processing object.

### BACKGROUND ART

There are a variety of known technologies for processing a surface of a processing object (cf. Patent Document 1 and Non-patent Documents 1 and 2): for example, a known technology is to apply a hydrofluoric acid (HF) solution containing 0.1%-several % HF in pure water, onto a surface of a silicon (Si) wafer to remove a silicon dioxide (SiO₂) film from the surface of the Si wafer. Another known technology is to place a Si wafer in a chamber, introduce an active gas (e.g., hydrogen containing NF₃) into the chamber, ionize the active gas into plasma, and remove the SiO₂ film from the surface of the Si wafer by ions of the active gas. A further known technology is to place a processing object in a chamber, introduce a gas such as oxygen or nitrogen into the chamber, ionize the gas into plasma by microwave, and decompose and remove organic matter from the surface of the processing object by the plasma.

Patent Document 1: Japanese Patent Application Laid-open No. H6-190269.
Non-patent Document 1: T. Hattori, et al., J. Electrochem. Soc., Vol. 145(1998) pp. 3278-3284.
Non-patent Document 2: J. Kikuchi, et al., Jpn. J. Appl. Phys. Vol. 35 (1996) pp. 1022-1026.

### DISCLOSURE OF THE INVENTION

### Problem to be Solved by the Invention

However, the conventional surface processing technologies as described above have the following problems. Namely, the technology of removing the SiO₂ film from the surface of the Si wafer with the HF solution uses a large amount of the HF solution and it is not easy to handle the HF solution and to perform disposal of waste because HF is harmful. The technology of removing the SiO₂ film from the surface of the Si wafer by the plasma of active gas has the following problem: SiO₂ removed from the surface of the Si wafer is not forced to flow out of the chamber, the impurity is deposited on the inner surface of the chamber during long-haul processing, and the deposited material adheres again to the surface of the Si wafer. Furthermore, the surface processing technology with the plasma has the problem that ions of the plasma collide with the surface of the processing object to damage the surface.

The present invention has been accomplished in order to solve the above problems and an object of the present invention is to provide a surface processing method and surface processing apparatus capable of readily processing the surface while suppressing the damage to the surface of the processing object.

### Means to Accomplish the Object

A surface processing method according to the present invention comprises the steps of: applying a processing liquid onto a surface of a processing object; and irradiating the applied processing liquid with an electron beam to process the surface of the processing object. A surface processing apparatus according to the present invention comprises: processing liquid applying means to apply a processing liquid onto a surface of a processing object; and electron beam irradiating means to irradiate the processing liquid applied by the processing liquid applying means, with an electron beam. In the surface processing method and surface processing apparatus according to the present invention, the processing liquid is applied onto the surface of the processing object and the applied processing liquid is irradiated with the electron beam to process the surface of the processing object. When the processing liquid on the surface of the processing object is irradiated with the electron beam, the processing liquid is ionized or radicalized to become active, thereby effectively processing the surface of the processing object.

In the surface processing method according to the present invention, the processing liquid is preferably an etching liquid for etching the surface of the processing object, or is also preferably functional water. A thickness of the processing liquid on the surface of the processing object is preferably in the range of 10 μm to 300 μm. Preferably, while heating the surface of the processing object and also heating the processing liquid, the processing liquid is applied onto the surface of the processing object. The processing liquid is preferably sprayed to be applied onto the surface of the processing object. Preferably, during the step of applying the processing liquid onto the surface of the processing object, the processing object is kept in an atmosphere of nitrogen gas, ozone gas, or high-pressure ozone gas.

In the surface processing method according to the present invention, preferably, the processing object is a Si wafer having a SiO₂ film on a surface thereof, the processing liquid is a HF solution, and the HF solution applied on the surface of the Si wafer is irradiated with the electron beam to remove the SiO₂ film on the surface of the Si wafer. Preferably, the processing object is a semiconductor, metal, glass, or ceramic material, and the functional water applied on the surface of the processing object is irradiated with the electron beam to remove an organic impurity, fine particle, or metal impurity from the surface of the processing object. Furthermore, preferably, the processing object is a semiconductor wafer having a resist film on a surface thereof, and the functional water applied on the surface of the semiconductor wafer is irradiated with the electron beam to remove the resist film from the surface of the semiconductor wafer.

In the surface processing apparatus according to the present invention, the processing liquid applying means preferably applies an etching liquid for etching the surface of the processing object, as the processing liquid onto the surface of the processing object, or it also preferably applies functional water as the processing liquid onto the surface of the processing object. The processing liquid applying means preferably applies the processing liquid onto the surface of the processing object so that a thickness of the processing liquid on the surface of the processing object can fall within the range of 10 μm to 300 μm. The surface processing apparatus preferably further comprises first heating means to heat the surface of the processing object; and second heating means to heat the processing liquid to be applied onto the surface of the processing object. The processing liquid applying means preferably sprays and applies the processing liquid onto the surface of the processing object. The surface processing apparatus preferably further comprises atmosphere setting means to keep the processing object in an atmosphere of nitrogen gas, ozone gas, or high-pressure ozone gas during applying the processing liquid onto the surface of the processing object. It also preferably further comprises a nitrogen gas sprayer to spray nitrogen gas to a portion irradiated with the electron beam by the electron beam means.

### Effect of the Invention

The present invention successfully provides the method and apparatus capable of readily processing the surface while suppressing the damage to the surface of the processing object.

### BRIEF DESCRIPTION OF THE DRAWINGS

FIG. 1 is a configuration diagram of surface processing apparatus 1 according to an embodiment of the present invention.

FIG. 2 is a graph showing penetration distances of an electron beam in water.

FIG. 3 is a graph showing a relation between time necessary for etching of SiO₂ film, and concentration of HF solution in Example 1.

FIG. 4 is a graph of concentrations of ozone generated in water with irradiation of water with an electron beam.

FIG. 5 is a graph in a case where organic matter is removed by irradiating organic impurities adhering to a surface of Si, with an electron beam.

### DEFINITION OF REFERENCE SYMBOLS

1 surface processing apparatus; 2 processing object; 10 sample table; 11 sucker; 12 rotator; 20 processing liquid applicator; 21 processing liquid application tube; 22 processing liquid supply; 30 electron beam irradiator; 31 vacuum chamber; 32 Be film; 33 thermionic source; 34 acceleration electrode; 35 voltage source; 36 atmosphere gas sprayer; 37 atmosphere gas supply; 40 shield container; 41 nitrogen gas sprayer.

### BEST MODES FOR CARRYING OUT THE INVENTION

The best mode for carrying out the present invention will be described below in detail with reference to the accompanying drawings. In the description of the drawings the same elements will be denoted by the same reference symbols, without redundant description.

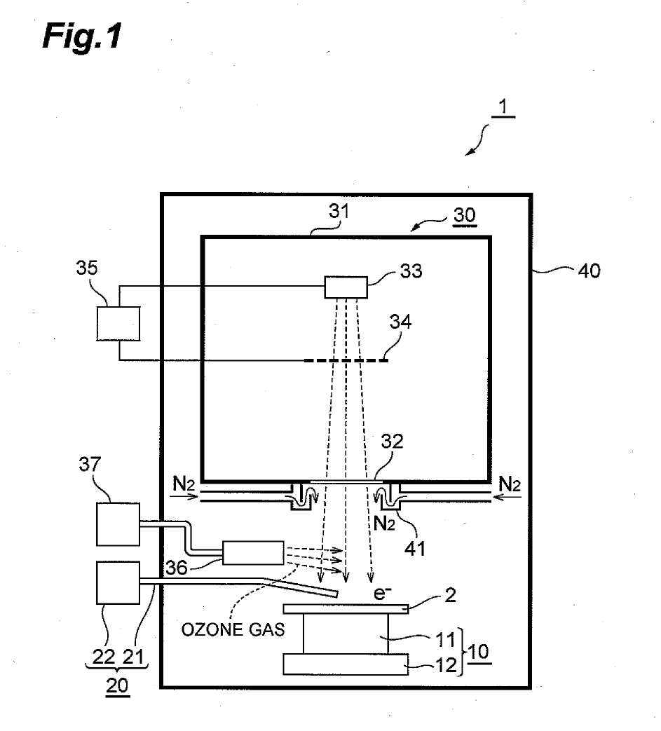

FIG. 1 is a configuration diagram of surface processing apparatus 1 according to an embodiment of the present invention. The surface processing apparatus 1 shown in this figure is an apparatus for processing a surface of a processing object 2 and has a sample table 10 to carry and rotate the processing object 2, a processing liquid applicator 20 to apply a processing liquid onto the surface of the processing object 2, an electron beam irradiator 30 to irradiate the processing liquid applied by the processing liquid applicator 20, with an electron beam, and a shield container 40.

The sample table 10 includes a sucker 11 and a rotator 12. The sucker 11 sucks and fixes the processing object 2 by vacuum suction. The rotator 12 rotates the processing object 2 together with the sucker 11. The processing liquid applicator 20 includes a processing liquid application tube 21 and a processing liquid supply 22. The processing liquid application tube 21 applies the processing liquid supplied from the processing liquid supply 22, onto the surface of the processing object 2 sucked and fixed by the sucker 11.

The electron beam irradiator 30 includes a vacuum chamber 31, a beryllium (Be) film 32, a thermionic source 33, an acceleration electrode 34, a voltage source 35, an atmosphere gas sprayer 36, an atmosphere gas supply 37, and a nitrogen gas sprayer 41. The interior of the vacuum chamber 31 can be evacuated and the thermionic source 33 and acceleration electrode 34 are arranged inside it. A part of a bottom surface of the vacuum chamber 31 is made of the Be film 32 capable of transmitting the electron beam from the interior to the exterior. The thickness of this Be film 32 is, for example, 10 μm-20 μm. This film does not always have to be the Be film, but may be any other metal film that can readily transmit electrons and that can stand against vacuum, e.g., diamond film or Si film.

The thermionic source 33 is a source that emits thermal electrons when heated by power supplied from the voltage source 35. The acceleration electrode 34 is set at a higher potential (e.g., several ten kV-200 kV) than the thermionic source 33 by the voltage source 35 so that it can accelerate the thermal electrons emitted from the thermionic source 33, toward the Be film 32. The atmosphere gas sprayer 36 as an atmosphere setting device for setting the atmosphere around the processing object 2 sprays ozone gas or high-pressure ozone gas or the like supplied from the atmosphere gas supply 37, whereby it can supply the ozone gas into pure water. The nitrogen gas sprayer constructed in a labyrinthine form is arranged at the part of Be film 32 in order to prevent oxidation of the Be film 32.

The shield container 40 functions to prevent X-rays from leaking from the interior thereof to the exterior and is made of lead. The following components are located inside the shield container 40: sample table 10, the distal end of processing liquid application tube 21, vacuum chamber 31, Be film 32, thermionic source 33, acceleration electrode 34, and atmosphere gas sprayer 36.

The processing liquid is a liquid for etching or cleaning the surface of the processing object 2, e.g., a HF solution or functional water. The functional water is a concept that embraces electrolyzed water (pure water, hydrogen water, ionic water, oxidized/reduced water, and water containing various gases (nitrogen gas, Ar gas, He gas, oxygen gas, etc.)) and ozone water. The processing liquid may be a cleaning liquid such as an SC1 solution or SC2 solution used in wet cleaning of semiconductors.

There are no particular restrictions on a material of the processing object 2, but in a case where the processing liquid is an etching liquid, the processing object is one made of a material that can be etched with the processing liquid. When the processing liquid is the functional water, the processing object 2 is, for example, a semiconductor, metal, glass, ceramic, or other material, and the processing liquid removes organic impurities, fine particles, metal impurities, etc. adhering to the surface of the processing object 2. For example, the processing object 2 is a semiconductor wafer having a resist film on a surface thereof, and the functional water applied on the surface of the semiconductor wafer is irradiated with an electron beam to remove the resist film from the surface of the semiconductor wafer.

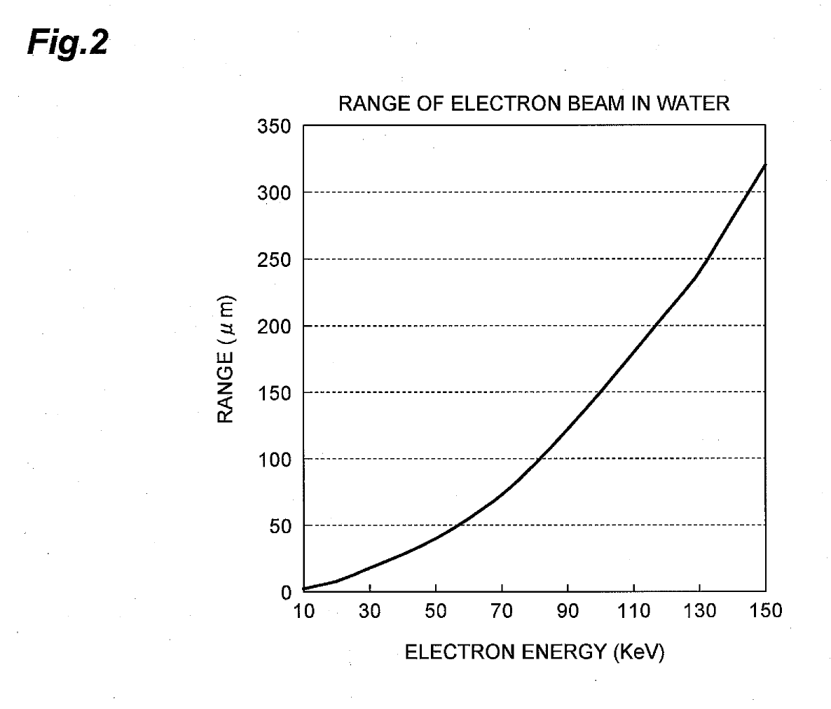

The following will describe a surface processing method according to the present embodiment using the surface processing apparatus 1. The processing object 2 is sucked and fixed by the sucker 11 and rotated by the rotator 12. In that state, the processing liquid supplied from the processing liquid supply 22 is applied through the processing liquid application tube 21 onto the surface of the processing object 2. Then thermal electrons emitted from the thermionic source 33 are accelerated by the acceleration electrode 34 and pass through the Be film 32 to impinge upon the processing liquid on the surface of the processing object 2. When the processing liquid on the surface of the processing object 2 is irradiated with the electron beam, the processing liquid is ionized or radicalized to become active, thereby effectively processing the surface of the processing object 2. FIG. 2 shows penetration distances of the electron beam in water. It is seen that when the energy of the electron beam is 100 keV, the electron beam penetrates water by the distance of 150 μm to impart the entire energy to water. It is understood that since the energy of the electron beam is high, a layer of extremely active water is made in the surface of water.

The surface processing apparatus 1 or surface processing method according to the present embodiment enables easy processing of the surface of the processing object 2 because, even in the case of the processing liquid containing a harmful component, the content of the harmful component can be reduced or an amount of the processing liquid to be used can be reduced. It is also feasible to increase the processing efficiency and thus to reduce the processing time.

In the conventional surface processing technology with the plasma, molecules with high energy collide with the surface of the processing object, and thus the conventional technology had the problem that the surface was damaged. In contrast to it, the present embodiment adopts the configuration to irradiate the processing liquid applied in the appropriate thickness on the surface of the processing object, with the electron beam. For this reason, the energy of electrons upon collision with the surface of the processing object is very small, e.g., 10 keV or less and the mass of electron is about one two-thousandth of that of ion; therefore, this configuration can prevent the surface of the processing object from being damaged.

Since the acceleration voltage of thermal electrons is from several ten kV to 200 kV as described above, the thickness of the processing liquid on the surface of the processing object 2 is preferably in the range of 10 μm to 300 μm. When the thickness of the processing liquid is set in this range, the processing liquid is effectively activated, so that the processing of the surface of the processing object 2 can be effectively carried out. The thickness of the processing liquid is adjusted by the viscosity of the processing liquid and/or the rotating speed of the processing object.

The sample table 10 is provided, for example, with a heater as a first heating device to heat the surface of the processing object 2, and the processing liquid supply 22 is provided, for example, with a heater as a second heating device to heat the processing liquid to be applied onto the surface of the processing object 2; this configuration is preferably applicable in such a manner that the processing solution is applied onto the surface of the processing object 2 while heating the surface of the processing object 2 and also heating the processing liquid. When this configuration is adopted, the processing liquid on the surface of the processing object 2 is more effectively activated upon irradiation with the electron beam, so that the processing of the surface of the processing object 2 can be more effectively carried out.

On the occasion of applying the processing liquid from the processing liquid application tube 21 onto the surface of the processing object 2, it is preferable to spray and apply the processing liquid. When this method is adopted, the processing liquid ejected from the tip of the processing liquid application tube 21 is more effectively activated as irradiated with the electron beam before arrival at the surface of the processing object 2, so that the processing of the surface of the processing object 2 can be more effectively carried out.

### EXAMPLE 1

The following will describe more specific Example 1 of the surface processing method using the surface processing apparatus 1. In Example 1, a Si wafer was used as the processing object 2 and a HF solution containing 0.01%-1% HF in pure water was used as the processing liquid. The HF solution was applied onto a surface of the Si wafer under rotation, and the HF solution on the surface had the thickness of about 100 μm. In this state, the HF solution on the surface of the Si wafer was irradiated with an electron beam having the energy of several ten keV to 200 keV. As a result, though the HF concentration was lower than in the conventional technologies, the SiO₂ film on the surface of the Si wafer was etched with high efficiency.

When the HF solution on the surface of the Si wafer is irradiated with the electron beam, molecules in the HF solution are ionized or radicalized to become active. It is believed that the etching rate of SiO₂ with the BF solution is dependent upon the HF molecule concentration [HF] and HF₂⁻ ion concentration [HF₂] in the solution and proportional to “[HF]+7[HF₂⁻]+0.3[HF]².” When the HF solution is irradiated with the electron beam, F⁻ ions are generated in the HF solution and the F⁻ ions combine with HF molecules to generate HF₂⁻ ions. Therefore, when compared with the case without irradiation with the electron beam, the surface of the Si wafer is processed with the HF solution irradiated with the electron beam to become active, so that the SiO₂ film on the surface of the Si wafer can be etched and removed in a shorter time.

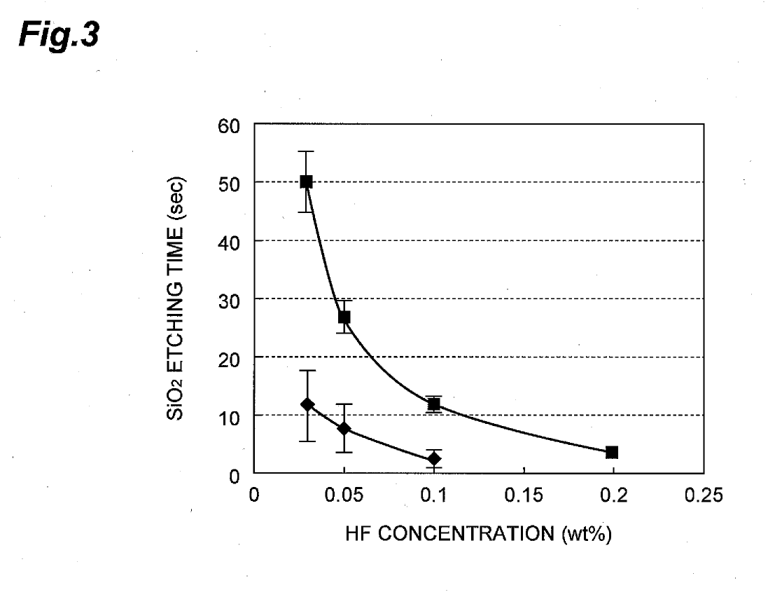

FIG. 3 is a graph showing a relation between the time necessary for etching of the SiO₂ film and the concentration of HF solution in Example 1. The thickness of the SiO₂ film was 160 nm, the acceleration voltage of the electron beam 100 kV, and the dose of electron beam radiation into the HF solution on the surface of the Si wafer 10 μA/cm². This figure also shows the result in the case without irradiation with the electron beam (Comparative Example 1). As apparent from this figure, the time necessary for etching of the SiO₂ film was approximately quarter on average in Example 1 with irradiation with the electron beam when compared with Comparative Example 1 without irradiation with the electron beam.

### EXAMPLE 2

The below will describe more specific Example 2 of the surface processing method using the surface processing apparatus 1. In Example 2, an object of a flat plate shape of a semiconductor, metal, glass, or a ceramic material was used as the processing object 2 and functional water as the processing liquid. Organic impurities, fine particles, or metal impurities were observed as adherent matter to the surface of the processing object. When the functional water was applied onto the surface of the processing object under rotation, the functional water on the surface had the thickness of about 100 μm. In this state, the functional water on the surface of the processing object was irradiated with the electron beam having the energy of several ten keV to 200 keV. As a result, the impurities adhering to the surface of the processing object were removed with high efficiency.

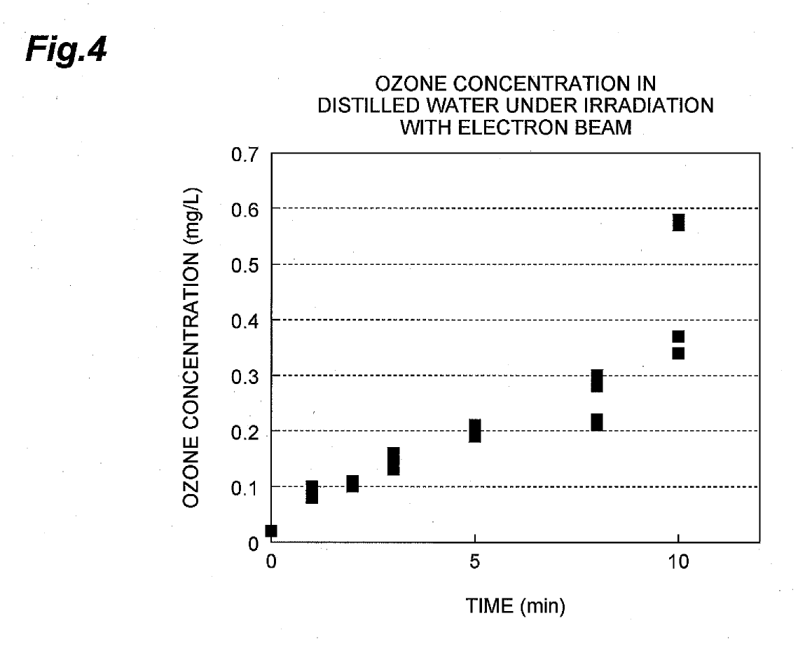

When the functional water on the surface of the processing object is irradiated with the electron beam, molecules in the functional water are ionized or radicalized, or ozone is generated. Since the functional water containing H⁺ ions, OH⁻ ions, or ozone thus generated is highly active, the impurities adhering to the surface of the processing object can be removed with high efficiency. FIG. 4 is a graph of ozone concentrations generated in water, in cases where the electron beam was irradiated into water. The irradiation condition with the electron beam was that a sample located at 1 cm from the Be film was irradiated through the Be film of 20 μm with the electron beam of 100 kV and 8 μA.

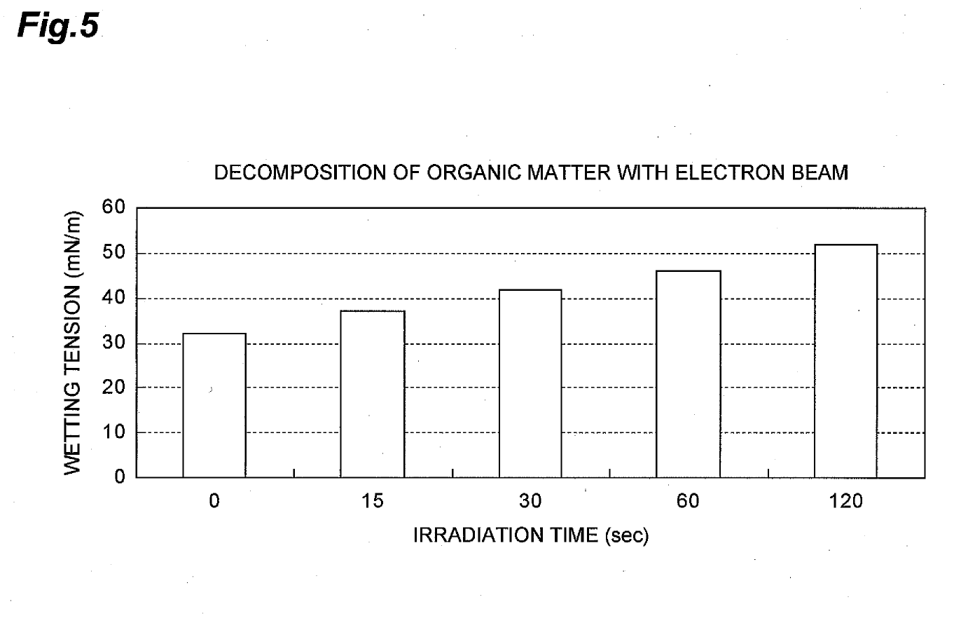

FIG. 5 is a graph in cases where organic impurities adhering to the surface of Si were irradiated with the electron beam to remove the organic matter. The horizontal axis represents the irradiation time with the electron beam and the vertical axis surface tension measured in order to check a state of contamination with the organic matter. The condition was that a sample located at 1 cm from the Be film was irradiated through the Be film of 20 μm with the electron beam of 110 kV and 6 μA. It is seen that the organic matter was effectively removed. Since the electron beam can be readily increased to several-mA order, it is feasible to perform quick organic decomposition processing.

### INDUSTRIAL APPLICABILITY

The present invention provides the surface processing method and surface processing apparatus capable of readily processing the surface while suppressing the damage to the surface of the processing object.

1. A surface processing method comprising the steps of: applying a processing liquid onto a surface of a processing object; and irradiating the applied processing liquid with an electron beam to process the surface of the processing object.

2. The surface processing method according to claim 1, wherein the processing liquid is an etching liquid for etching the surface of the processing object.

3. The surface processing method according to claim 1, wherein the processing liquid is functional water.

4. The surface processing method according to claim 1, wherein a thickness of the processing liquid on the surface of the processing object is in the range of 10 μm to 300 μm.

5. The surface processing method according to claim 1, wherein, while heating the surface of the processing object and also heating the processing liquid, the processing liquid is applied onto the surface of the processing object.

6. The surface processing method according to claim 1, wherein the processing liquid is sprayed to be applied onto the surface of the processing object.

7. The surface processing method according to claim 1, wherein during the step of applying the processing liquid onto the surface of the processing object, the processing object is kept in an atmosphere of nitrogen gas, ozone gas, or high-pressure ozone gas.

8. The surface processing method according to claim 2, wherein the processing object is a Si wafer having a SiO₂ film on a surface thereof, the processing liquid is a HF solution, and the HF solution applied on the surface of the Si wafer is irradiated with the electron beam to remove the SiO₂ film on the surface of the Si wafer.

9. The surface processing method according to claim 3, wherein the processing object is a semiconductor, metal, glass, or ceramic material, and the functional water applied on the surface of the processing object is irradiated with the electron beam to remove an organic impurity, fine particle, or metal impurity from the surface of the processing object.

10. The surface processing method according to claim 3, wherein the processing object is a semiconductor wafer having a resist film on a surface thereof, and the functional water applied on the surface of the semiconductor wafer is irradiated with the electron beam to remove the resist film from the surface of the semiconductor wafer.

11. A surface processing apparatus comprising: processing liquid applying means to apply a processing liquid onto a surface of a processing object; and electron beam irradiating means to irradiate the processing liquid applied by the processing liquid applying means, with an electron beam.

12. The surface processing apparatus according to claim 11, wherein the processing liquid applying means applies an etching liquid. for etching the surface of the processing object, as the processing liquid onto the surface of the processing object.

13. The surface processing apparatus according to claim 11, wherein the processing liquid applying means applies functional water as the processing liquid onto the surface of the processing object.

14. The surface processing apparatus according to claim 11, wherein the processing liquid applying means applies the processing liquid onto the surface of the processing object so that a thickness of the processing liquid on the surface of the processing object can fall within the range of 10 μm to 300 μm.

15. The surface processing apparatus according to claim 11, further comprising first heating means to heat the surface of the processing object; and second heating means to heat the processing liquid to be applied onto the surface of the processing object.

16. The surface processing apparatus according to claim 11, wherein the processing liquid applying means sprays and applies the processing liquid onto the surface of the processing object.

17. The surface processing apparatus according to claim 11, further comprising atmosphere setting means to keep the processing object in an atmosphere of nitrogen gas, ozone gas, or high-pressure ozone gas during applying the processing liquid onto the surface of the processing object.

18. The surface processing apparatus according to claim 11, further comprising a nitrogen gas sprayer to spray nitrogen gas to a portion irradiated with the electron beam by the electron beam means.
